(19) United States
(12) Patent Application Publication
(10) Pub. No.: US 2025/0003050 A1
(43) Pub. Date: Jan. 2, 2025

(54) MASK PLATE ASSEMBLY AND EVAPORATION DEVICE

(71) Applicant: HKC CORPORATION LIMITED, Shenzhen (CN)

(72) Inventors: Yao LI, Shenzhen (CN); Junfeng XIE, Shenzhen (CN)

(21) Appl. No.: 18/666,865

(22) Filed: May 17, 2024

(30) Foreign Application Priority Data
Jun. 28, 2023 (CN) 202310788740.5

(51) Int. Cl. C23C 14/04; C23C 14/54

(52) U.S. Cl. CPC C23C 14/042; C23C 14/545

(57) ABSTRACT

Some embodiments of the present disclosure provide a mask plate assembly and an evaporation device. The mask plate assembly includes one or more mask plates and one or more electrode pairs. The mask plate defines multiple openings. Each electrode pair includes two electrodes. The two electrodes are disposed on one of the one or more mask plates and spaced apart from each other. Each of the one or more mask plates includes a piezoelectric material.

### CROSS REFERENCE TO RELATED APPLICATIONS

The present application claims priority to Chinese Patent Application No. 202310788740.5 filed on Jun. 28, 2023, the content of which is herein incorporated by reference in its entirety.

### TECHNICAL FIELD

Embodiments of the present disclosure relate to the field of OLED (organic light emitting diode) display process technologies, and in particular to a mask plate assembly and an evaporation device.

### BACKGROUND

The LCD (liquid crystal display) and the OLED (organic light-emitting diode) are two mainstream display modes. Compared to the LCD screens, the OLED screens have the characteristics of simple structure, low power consumption, high contrast, thin thickness, bright colors, wide viewing angle, fast reaction speed, and wide temperature range, etc. The OLED screens are now widely used in the commercial field, the communication field, the computer field, the consumer electronics field, the industry and the transportation field.

At present, in the production of the OLED, the FMM (fine metal mask) is usually used to deposit organic materials on the anode layer by vacuum evaporation, and then the metal cathode is deposited by hot evaporation or sputtering mode. Therefore, the FMM is an important determinant of the OLED display resolution. The FMM defines multiple openings and organic materials are deposited on the array substrate through the multiple openings to form sub pixels. Thus, it may be seen that the shape of the opening region determines the size of the evaporation area of organic materials. However, the FMM in the use of the process is deformed easily, such that the shape and size of the openings will be altered, and the stability of the product will be affected.

### SUMMARY OF THE DISCLOSURE

Some embodiments of the present disclosure provide a mask plate assembly and an evaporation device.

One technical solution adopted by some embodiments of the present disclosure is to provide a mask plate assembly. The mask plate assembly includes one or more mask plates and one or more electrode pairs. Each of the one or more mask plates defines a plurality of openings. Each of the one or more electrode pairs include two electrodes, and the two electrodes are disposed on one of the one or more mask plates and spaced apart from each other. The two electrodes are configured to apply a compensation voltage to the one of the one or more mask plates. Each of the one or more mask plates comprises a piezoelectric material.

Another technical solution adopted by some embodiments of the present disclosure is to provide an evaporation device. The evaporation device includes a mask plate assembly and a control circuit. The mask plate assembly includes one or more mask plates and one or more electrode pairs. Each of the one or more mask plates defines a plurality of openings. Each of the one or more electrode pairs include two electrodes, and the two electrodes are disposed on one of the one or more mask plates and spaced apart from each other. The two electrodes are configured to apply a compensation voltage to the one of the one or more mask plates. Each of the one or more mask plates comprises a piezoelectric material. The control circuit is electrically connected to each of the one or more mask plates. The control circuit is configured to obtain a deformation parameter of each of the one or more mask plates, and apply a compensation voltage to each of the one or more mask plates according to the deformation parameter of each of the one or more mask plates, so that each of the one or more mask plates will occur the reverse piezoelectric effect.

### BRIEF DESCRIPTION OF THE DRAWINGS

FIG. 1a is a structural schematic view of a mask plate assembly according to a first embodiment of the present disclosure.

FIG. 1b is a structural schematic sectional view of the mask plate assembly along a line A-A in FIG. 1a according to some embodiments of the present disclosure.

FIG. 2a is a comparison schematic view of a mask plate before and after a deformation and after applied a compensation voltage in FIG. 1a according to some embodiments of the present disclosure.

FIG. 2b is a structural schematic sectional view of a mask plate along a line B-B in FIG. 2a according to some embodiments of the present disclosure.

FIG. 3a is a structural schematic view of a mask plate assembly according to a second embodiment of the present disclosure.

FIG. 3b is a structural schematic sectional view of the mask plate assembly along a line C-C in FIG. 3a according to some embodiments of the present disclosure.

FIG. 4 is a structural schematic view of a mask plate assembly according to a third embodiment of the present disclosure.

FIG. 5 is a structural schematic view of a mask plate assembly according to a fourth embodiment of the present disclosure.

FIG. 6a is a structural schematic view of a mask plate assembly according to a fifth embodiment of the present disclosure.

FIG. 6b is a structural schematic sectional view of the mask plate assembly along a line D-D in FIG. 6a according to some embodiments of the present disclosure.

FIG. 7 is a structural schematic view of a mask plate assembly according to a sixth embodiment of the present disclosure.

FIG. 8 is a structural schematic view of an evaporation device according to some embodiments of the present disclosure.

FIG. 9 is a functional module structural schematic view of a control circuit of the evaporation device shown in FIG. 8 according to a first embodiment of the present disclosure.

FIG. 10 is a functional module structural schematic view of a control circuit of the evaporation device shown in FIG. 8 according to a second embodiment of the present disclosure.

FIG. 11 is a functional module structural schematic view of a control circuit of the evaporation device shown in FIG. 8 according to a third embodiment of the present disclosure.

FIG. 12 is a flowchart of a method of an evaporation device applying a compensation voltage according to one embodiment of the present disclosure.

FIG. 13 is a flowchart of a method of an evaporation device applying a compensation voltage according to another embodiment of the present disclosure.

Reference numerals in drawings: 1—mask plate assembly; 11—mask plate; 111—opening; 12—electrode pair; 13—first sensor; 14—main mask frame; 141—sub mask frame; 142—fist conductive layer; 2—control circuit; 21—calculation module; 22—coltage compensation module; 23—storage module; 24—voltage detecting module; 3—second sensor.

### DETAILED DESCRIPTION

Technical solutions in the embodiments of the present disclosure will be clearly and completely described below by referring to the accompanying drawings in the embodiments of the present disclosure. Obviously, the described embodiments are only some of but not all of the embodiments of the present disclosure. Based on the embodiments in the present disclosure, all other embodiments obtained by any ordinary skilled person in the art without making creative work shall fall within the scope of the present disclosure.

Terms “first”, “second” and “third” herein are used for descriptive purposes only and shall not be interpreted as indicating or implying relative importance or implicitly specifying the number of indicated technical features. Therefore, a feature defined by the “first”, “second”, or “third” may explicitly or implicitly include at least one such feature. In the present disclosure, “A and/or B” indicates including A only, or including B only, or including both A and B. In the description of the present disclosure, “a plurality of” means at least two, such as two, three, and so on, unless otherwise expressly and specifically limited. All directional indications in the present disclosure (such as up, down, left, right, front, rear, . . . ) are used only to explain relative position relationship, movement, and the like, between components at a particular posture (as shown in the drawings). When the posture is changed, the directional indications may change accordingly. In addition, terms “include” and “have” and any variations thereof are intended to cover non-exclusive inclusion. For example, a process, a method, a system, a product, or an apparatus including a series of operations or units is not limited to the listed operations or units, but may further include operations or units that are not listed, or include other operations or units that are inherent to the process, the method, the product, or the apparatus.

The “embodiment” of the present disclosure may mean that a particular feature, structure, or property described in an embodiment may be included in at least one embodiment of the present disclosure. Presence of the phrase at various sections in the specification does not necessarily mean a same embodiment, nor is it a separate embodiment or an alternative embodiment that is mutually exclusive with other embodiments. Any ordinary skilled person in the art shall explicitly or implicitly understand that the embodiments described herein may be combined with other embodiments.

In the related art, the materials of the FMM mainly include metal materials or composite materials of metals and resins. When the FMM is applied to a vacuum evaporation of OLED screens, organic materials are deposited on a surface of an array substrate through several openings on the FMM to form several sub pixels with a regular shape and a regular size. During the evaporation process, organic materials deposited on the surface of FMM will release heat, and the metallic FMM will expend when heated, such that the FMM will be deformed easily and the deposition of the organic materials on the array substrate is irregular, thereby forming sub pixels with irregular shapes and sizes, and affecting the stability or consistency of the product.

For this reason, some embodiments of the present disclosure provide a mask plate assembly and an evaporation device. The mask plate assembly may compensate a deformation of a mask plate caused by heat or its own gravity, thereby avoiding irregular deposition of organic materials caused by a deformation of the mask plate, and effectively improving the stability or consistency of the prepared display panel.

The present disclosure is described in detail below in conjunction with the accompanying drawings and embodiments.

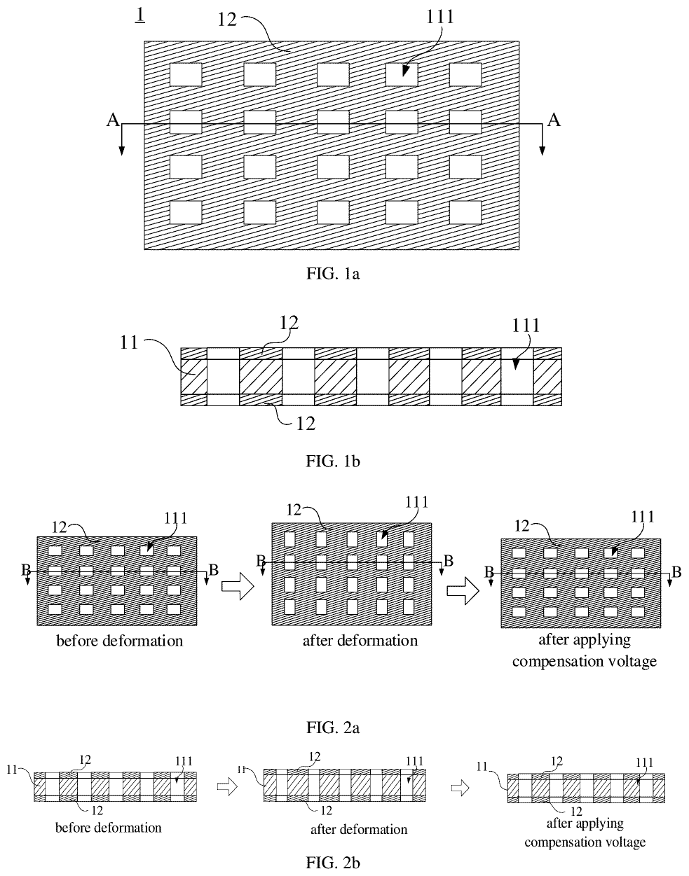

Referring to FIG. 1a to FIG. 2b, FIG. 1a is a structural schematic view of a mask plate assembly according to a first embodiment of the present disclosure, FIG. 1b is a structural schematic sectional view of the mask plate assembly along a line A-A in FIG. 1a according to some embodiments of the present disclosure, FIG. 2a is a comparison schematic view of a mask plate before and after a deformation and after applied a compensation voltage in FIG. 1a according to some embodiments of the present disclosure, and FIG. 2b is a structural schematic sectional view of a mask plate along a line B-B in FIG. 2a according to some embodiments of the present disclosure. Some embodiments of the present disclosure provide a mask plate assembly 1. The mask plate assembly 1 may be used for vacuum evaporation in the manufacturing process of the OLED display panel, so that, in the manufacturing process of the OLED display panel, RGB organic substances will be deposited accurately and finely in a pixel region of an array substrate to form pixels, thereby improving the resolution and yield of the product. It should be understood that the application of the mask plate assembly 1 in the present disclosure is not limited to the manufacturing process of the OLED display panel, and the mask plate assembly 1 may also be used for the deposition process of other products.

The mask plate assembly 1 may include one or more mask plates 11 and one or more electrode pairs 12. Each mask plate 11 defines a plurality of openings 111. The plurality of openings 111 may be arranged in an array. During a vacuum evaporation process, each mask plate 11 coats a region to be evaporated of the array substrate to be evaporated, and organic molecules in an evaporation chamber are deposited on the predetermined position of the array substrate through the plurality of openings 111 to form several pixels. Each mask plate 11 includes a piezoelectric material. Referring to FIG. 2a and FIG. 2b, ordinary skilled person in the art may understand that during the evaporation process, each mask plate 11 may be deformed to a certain extent under the action of heat and its own gravity. Because the piezoelectric material has a piezoelectric characteristic, a corresponding potential difference will be generated inside each mask plate 11. That is, each mask plate 11 will occur a positive piezoelectric effect. Conversely, when a voltage which has the same size and opposite direction with the potential difference is applied to each mask plate 11, a mechanical stress will be generated inside each mask plate 11, so that each mask plate 11 will generate a corresponding reset deformation. that is, each mask plate 11 will occur a reverse piezoelectric effect and return to the state before the deformation.

As shown in FIG. 1b, each electrode pair 12 may include two electrodes. The two electrodes are disposed on one of the mask plates 11 and spaced apart from each other. The two electrodes are configured to apply a compensation voltage to the one of the mask plates 11, after the one of the mask plates 11 is deformed caused by heat or its own gravity, such that the one of the mask plates 11 generates the reset deformation corresponding to the compensation voltage. Through the above arrangement, the one of the mask plates 11 will have the piezoelectric characteristic. When each electrode pair 12 applies the compensation voltage to a corresponding one of the mask plates 11, the corresponding one of the mask plates 11 may occur the reverse piezoelectric effect and generate the corresponding reset deformation to compensate for the deformation caused by heat or its own gravity, thereby avoiding the occurrence of irregular organic material deposition caused by the deformation of the corresponding one of the mask plates 11, and effectively improving the stability or consistency of the prepared display panel. In this embodiment, two electrodes of each electrode pair 12 are respectively disposed on two opposite surfaces of one of the mask plates 11. That is, one of the two electrodes of the same one of the electrode pairs 12 is disposed on one of two opposite surfaces of the one of the mask plates 11; and the other of the two electrodes of the same one of the electrode pairs 12 is disposed on the other of two opposite surfaces of the one of the mask plates 11. Each of the two electrodes coats the entire corresponding surface. Two electrodes of each electrode pair 12 may be a metal film, and may be deposited on the two opposite surfaces of one of the mask plates 11 through the deposition process. The thickness of two electrodes of each electrode pair 12 is not limited here, and it may be 3000 Å˜5000 Å.

The material of each mask plate 11 may be the piezoelectric material. That is, each mask plate 11 is entirely made of the piezoelectric material, so that each mask plate 11 has the piezoelectric characteristic as a whole, thereby ensuring that the deformation of each mask plate 11 may be consistent when the compensation voltage is applied to the each mask plate 11. The piezoelectric material may include a piezoelectric ceramic, such as a barium titanate piezoelectric ceramic, a lead zirconate titanate piezoelectric ceramic or a lead magnesium niobate piezoelectric ceramic. As it should be, the piezoelectric material may also include an alloy of the piezoelectric ceramic and a metal to reduce manufacturing and use costs. In this embodiment, each mask plate 11 is made of the barium titanate piezoelectric ceramic.

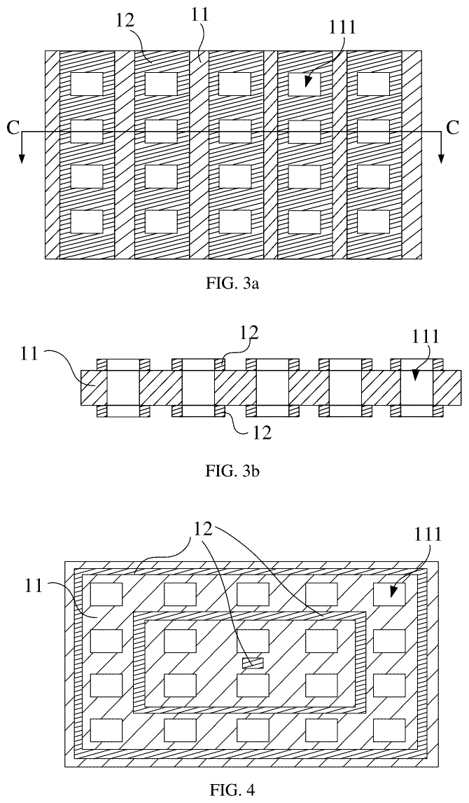

Referring to FIG. 3a and FIG. 3b, FIG. 3a is a structural schematic view of a mask plate assembly according to a second embodiment of the present disclosure and FIG. 3b is a structural schematic sectional view of the mask plate assembly along a line C-C in FIG. 3a according to some embodiments of the present disclosure. The second embodiment of the mask plate assembly provided in the present disclosure is substantially the same in structure as the first embodiment of the mask plate assembly. The difference is that in this embodiment, the mask plate assembly 1 includes a plurality of electrode pairs 12, and the plurality of electrode pairs 12 are disposed in different regions of one of the mask plates 11 at intervals. Each electrode pair 12 is configured to apply the compensation voltage to a corresponding region of the one of the mask plates 11 corresponding to the each electrode pair 12. In the same working period, different electrode pairs 12 may apply or not apply the compensation voltages, so that the reset deformations will be generated or not generated in different regions of the one of the mask plates 11.

Furthermore, in the same working period, the compensation voltages applied by different electrode pairs 12 may be the same, so that the different regions of one of the mask plates 11 may have the same reset deformation. The compensation voltages applied by different electrode pairs 12 may also be different, so that different regions of one of the mask plates 11 may have the different reset deformations. Furthermore, the two electrodes of the same electrode pair 12 are respectively disposed on two opposite surfaces of one of the mask plates 11, so that the compensation voltage applied by the two electrodes is evenly distributed on the corresponding region of the one of the mask plates 11, thereby avoiding an uneven deformation of the mask plate 11 caused by an uneven voltage distribution. In this embodiment, the plurality of electrode pairs 12 are arranged in parallel and spaced apart from each other. The plurality of electrode pairs 12 are arranged correspondingly to a plurality of columns of openings 111 in one-to-one correspondence. Each electrode pair 12 defines a plurality of open pores at the position of a corresponding column of openings 111 corresponding to the openings 111. Each electrode pair 12 is configured to apply the compensation voltage to the region where the corresponding column of openings 111 are located.

Referring to FIG. 4, FIG. 4 is a structural schematic view of a mask plate assembly according to a third embodiment of the present disclosure. The third embodiment of the mask plate assembly provided in the present disclosure is substantially the same in structure as the second embodiment of the mask plate assembly. The difference is that, the plurality of electrode pairs 12 are arranged in concentric rings. It should be understood that, in some cases, the temperature on the surface of each mask plate 11 varies gradually from the central region to the surrounding region, so that a plurality of annular temperature gradient regions are formed. By setting the plurality of electrode pairs 12 in concentric rings, different compensation voltages may be applied to different annular temperature gradient regions of each mask plate 11.

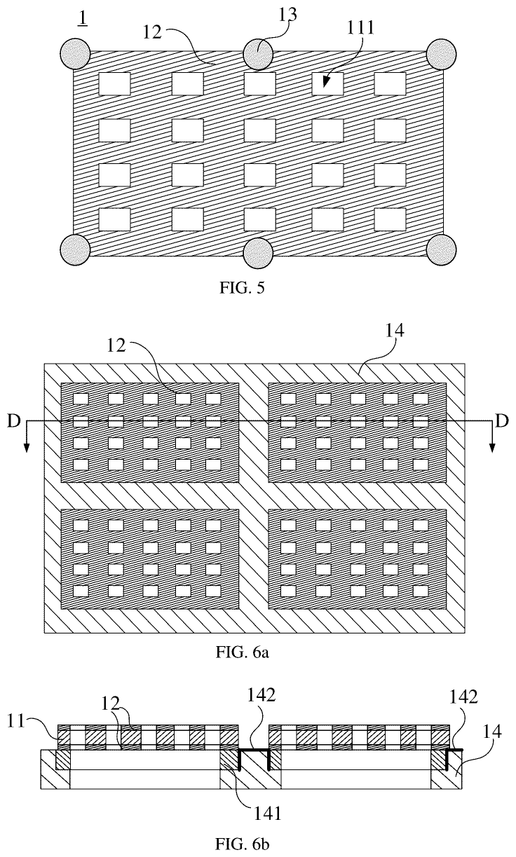

Referring to FIG. 5, FIG. 5 is a structural schematic view of a mask plate assembly according to a fourth embodiment of the present disclosure. The fourth embodiment of the mask plate assembly provided in the present disclosure is substantially the same in structure as the first embodiment of the mask plate assembly. The difference is that, in this embodiment, the mask plate assembly 1 may further include one or more first sensors 13. Each first sensor 13 may be disposed on a corresponding one of the mask plates 11 to detect a deformation parameter of the corresponding one of the mask plates 11.

Each first sensor 13 may be a displacement sensor. The deformation parameter of each mask plate 11 may include a deformation direction and a deformation size. The position of each first sensor 13 disposed on the corresponding one of the mask plates 11 will change with the deformation of the corresponding one of the mask plates 11. Each first sensor 13 may determine the deformation direction and the deformation size of the corresponding one of the mask plates 11 based on its own position change. Alternatively, each first sensor 13 may be a temperature sensor. The deformation parameter of each mask plate 11 may include a temperature of each mask plate 11. Each first sensor 13 may be configured to detect the temperature of the corresponding one of the mask plates 11, and confirm the deformation of the corresponding one of the mask plates 11 at this time based on the temperature detected. In each specific temperature condition, each mask plate 11 will arise the deformation corresponding to the temperature condition. In this embodiment, the shape of each mask plate 11 is rectangular, and each first sensor 13 is a displacement sensor. Six first sensors 13 are spaced circumferentially along the edge of one of the mask plates 11. Each corner is arranged with one first sensor 13 and the midpoint of the long edge of the one of the mask plates 11 is arranged with another one first sensor 13.

It should be understood that when the plurality of electrode pairs 12 are disposed on one of the mask plates 11, the region of one of the mask plates 11 corresponding to each electrode pair 12 is arranged with the first sensor 13 to detect the deformation directions and the deformation sizes of different regions of the one of the mask plates 11, thereby confirming the compensation voltages required for different regions through their respective deformation directions and deformation sizes, and applying the compensation voltage to the corresponding region through the corresponding electrode pair 12. Of course, the first sensor 13 corresponding to one region may be used to detect the temperatures of other regions of the one of the mask plates 11, thereby confirming the compensation voltages required by other regions, and applying the compensation voltage to the corresponding region through the corresponding electrode pair 12.

Referring to FIG. 6a and FIG. 6b, FIG. 6a is a structural schematic view of a mask plate assembly according to a fifth embodiment of the present disclosure, and FIG. 6b is a structural schematic sectional view of the mask plate assembly along a line D-D in FIG. 6a according to some embodiments of the present disclosure. The fifth embodiment of the mask plate assembly provided in the present disclosure is substantially the same in structure as the first embodiment of the mask plate assembly. The difference is that, in this embodiment, the mask plate assembly 1 further include a main mask frame 14 and a plurality of sub mask frames 141 arranged on the main mask frame 14. The plurality of sub mask frames 141 are regularly arranged on the main mask frame 14. The number of the one or more mask plates 11 is two or more. The number of the one or more mask plates 11 is the same as that of the plurality of sub mask frames 141. Each sub mask frame 141 is arranged with one mask plate 11. In this way, the mask plate assembly 1 will be suitable for making OLED displays with large size and high resolution.

Each sub mask frame 141 may be include or made of conducting materials such as alloys, etc., and the plurality of sub mask frames 141 may be electrically connected to each other. For example, the main mask frame 14 defines a plurality of step holes. The inner surfaces of two adjacent step holes are arranged with a first conductive layer 142. The first conductive layer 142 in one of the two adjacent step holes is connected to the first conductive layer 142 in the other of the two adjacent step holes. Each step hole is embedded with one sub mask frame 141. The sub mask frames 141 in two adjacent step holes are electrically connected to each other through a conductive sheet, so that the plurality of sub mask frames 141 are electrically connected to each other. Each mask plate 11 are arranged on a corresponding one of the mask frames 141. The electrodes of the electrode pairs 12 on the same side of the two or more mask plates 11 near the sub mask frames 141 are electrically connected to each other through the plurality of sub mask frames 141. In the use of the mask plate assembly 1, as long as different compensation voltages are applied to the electrodes of the electrode pairs 12 on the same side of the two or more mask plates 11 away from the mask frames 141, different compensation voltages may be applied respectively to different mask plates 11 or different regions of the same mask plate 11.

It should be understood that each sub mask frame 141 may also include or be made of insulating materials. A second conductive layer (not shown) is arranged on at least a surface and a outer side of each sub mask frame 141, and the surface and the outer side of each sub mask frame 141 are configured to be arranged with the mask plate 11. The second conductive layer of the plurality of sub mask frames 141 are electrically connected to the first conductive layer 142 which goes through the main mask frame14, and the electrodes of the electrode pairs 12 on the same side of the two or more mask plates 11 near the sub mask frames 141 are electrically connected to each other, thereby conveniently connected to the control circuit 2 (shown in FIG. 8).

It should be understood that each first sensor 13 may be arranged on the main mask frame 14 or a corresponding one of the plurality of sub mask frames 141. For example, a plurality of first sensors 13 are arranged on the main mask frame 14 to sense the temperature of the corresponding one of the mask plates 11.

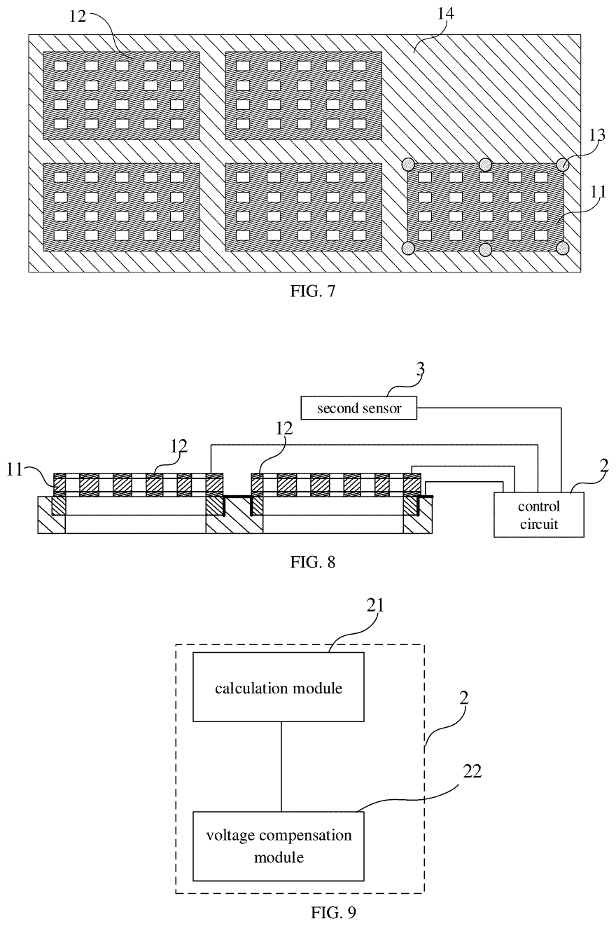

Referring to FIG. 7, FIG. 7 is a structural schematic view of a mask plate assembly according to a sixth embodiment of the present disclosure. The sixth embodiment of the mask plate assembly provided in the present disclosure is substantially the same in structure as the fifth embodiment of the mask plate assembly. The difference is that, in this embodiment, the first sensors 13 are only arranged on one mask plate 11. During the vacuum evaporation, the mask plate 11 without the first sensors 13 is aligned with and coats the region of the array substrate to be evaporated, and the one mask plate 11 with the first sensors 13 and the region of the array substrate to be evaporated are dislocated. It should be understood that in the same environmental condition, the deformations of the mask plates 11 with the same materials are also substantially the same. By detecting the deformation direction and deformation size of the one mask plate 11 with the first sensors 13, the deformation direction and the deformation size of the mask plate 11 without the first sensors 13 may be determined. The compensation voltage is applied to each mask plate 11 according to the deformation direction and deformation size of the each mask plate 11. Of course, in other embodiments, the temperature of the one mask plate 11 with the first sensors 13 is also may be detected to determine the temperature of the mask plate 11 without the first sensors13. The compensation voltage may be applied to each mask plate 11 according to the temperature of each mask plate 11. Since the mask plate 11 for evaporation is not arranged with the first sensors 13, the deformation effect of the first sensors 13 on the mask plate 11 may be avoided.

The mask plate assembly 1 provided by the some embodiments includes one or more mask plates 11 and one or more electrode pairs 12. Each mask plate 11 defines a plurality of openings 111. Each electrode pair 12 includes two electrodes. Two electrodes of each electrode pair 12 are disposed on one of the mask plates and spaced apart from each other. The two electrodes are configured to apply the compensation voltage to the one of the mask plates 11. Each mask plate 11 includes the piezoelectric material. Each mask plate 11 will have the piezoelectric characteristic by the above arrangement. When each electrode pair 12 applies the voltage to the corresponding one of the mask plates 11, the corresponding one of the mask plates 11 may occur the reverse piezoelectric effect and generate the corresponding reset deformation to compensate for the deformation caused by heat or its own gravity, thereby avoiding the occurrence of irregular deposition of organic materials due to the deformation of each mask plate11, and effectively improving the stability and consistency of the prepared display panel.

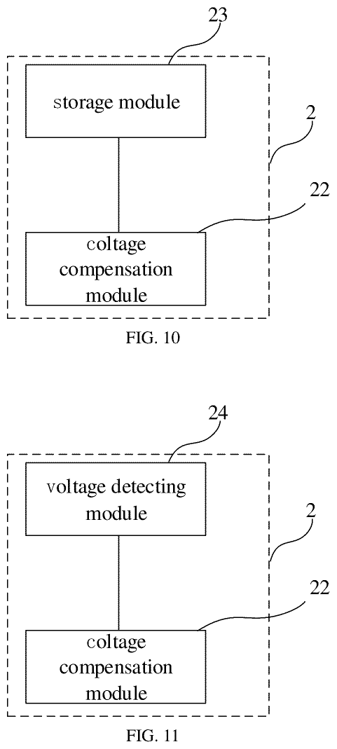

Referring to FIG. 8-FIG. 11, FIG. 8 is a structural schematic view of an evaporation device according to some embodiments of the present disclosure, FIG. 9 is a functional module structural schematic view of a control circuit of the evaporation device shown in FIG. 8 according to a first embodiment of the present disclosure, FIG. 10 is a functional module structural schematic view of a control circuit of the evaporation device shown in FIG. 8 according to a second embodiment of the present disclosure, and FIG. 11 is a functional module structural schematic view of a control circuit of the evaporation device shown in FIG. 8 according to a third embodiment of the present disclosure. The evaporation device is configured to make organic molecules adhere to the array substrate to be evaporated through the evaporation and condensation of organic materials under high vacuum, so that pixels are formed. In an embodiment, the evaporation device may include a mask plate assembly 1 and a control circuit 2. the mask plate assembly 1 may be the mask plate assembly 1 described in any of the above embodiments. The specific structure and function of the mask plate assembly 1 may be found in the above embodiments, and will not be repeated here. It should be understood that the evaporation device of the present disclosure also includes other functional assemblies, such as evaporation chamber and heating components, etc.

The control circuit 2 is electrically connected to each mask plate 11 through the electrode pair 12. The control circuit 2 is configured to obtain the deformation parameter of each mask plate 11, and apply the compensation voltage to the each mask plate 11 based on the deformation parameter of each mask plate 11, so that each mask plate 11 may have the reverse piezoelectric effect and generate the reset deformation to compensate for the deformation caused by heat or its own gravity, thereby avoiding the occurrence of irregular organic material deposition caused by the deformation of each mask plate 11, and effectively improving the stability of the product. The deformation parameter of each mask plate11 may include any one or more of the deformation direction and the deformation size of each mask plate 11, the temperature of each mask plate 11, and a piezoelectric voltage generated by the deformation of each mask plate 11.

In some embodiments, the evaporation device may also include a second sensor 3. The second sensor 3 is configured to detect the deformation direction and deformation size of each mask plate 11 or detect a temperature of each mask plate 11. The second sensor 3 is disposed outside each mask plate 11, and it may be disposed in a evaporation chamber or on a machine. When the second sensor 3 is configured to detect the deformation direction and the deformation size of each mask plate 11, the deformation direction and the deformation size may be determined according to the position change of each mask plate 11 before and after the deformation. For example, the second sensor 3 may include an image sensor. When the second sensor 3 is configured to detect the temperature of each mask plate 11, the second sensor 3 may judge the compensation voltage to be applied by directly detecting the temperature of each mask plate 11 itself. The second sensor 3 may also indirectly determine the temperature of each mask plate 11 by detect the ambient temperature of the evaporation chamber, thereby determining the compensation voltage to be applied.

Ordinary skilled person in the art may understand that, in the vacuum evaporation process, the mask plate 11 is involved in the evaporation process as an important consumable. The second sensor 3 is disposed outside each mask plate 11, thereby greatly reducing the consumption of sensors, improving the utilization rate of sensors, and effectively reducing the process cost. Furthermore, the deformation effect of the second sensor 3 on the mask plate 11 will be avoided by setting the second sensor 3 outside each mask plate 11.

Referring to FIG. 9, the control circuit 2 may include a calculation module 21 and a voltage compensation module 22. The calculation module 21 is configured to calculate the piezoelectric voltage generated by the deformation of each mask plate 11 according the deformation direction and the deformation size of each mask plate 11. The voltage compensation module 22 is configured to apply the compensation voltage which has the same size and opposite direction with the piezoelectric voltage to each mask plate 11, according to a parameter of the piezoelectric voltage calculated by the calculation module 21. In this way, each mask plate 11 may have the reverse piezoelectric effect and generate the corresponding reset deformations to compensate for the deformation caused by heat or its own gravity.

Referring to FIG. 10, the control circuit 2 may include a storage module 23 and the voltage compensation module 22. The storage module 23 stores a corresponding relationship between the temperature and the compensation voltage of each mask plate 11. The voltage compensation module 22 obtains the compensation voltage according to the obtained temperature of each mask plate 11 and the corresponding relationship between the temperature and the compensation voltage of each mask plate 11, and applies the compensation voltage to each mask plate 11. It should be understood that the corresponding relationship between the temperature and the compensation voltage of each mask plate 11, is obtained by conducting experimental tests in advance, and the corresponding relationship between the temperature and the compensation voltage of each mask plate 11 is stored in the storage module 23 of the control circuit 2. The voltage compensation module 22 directly obtains the compensation voltage through the table lookup or the simulation calculation based on the obtained temperature of the mask plate 11, thereby simplifying the response operation of the control circuit.

Referring to FIG. 11, the control circuit 2 may include a voltage detecting module 24 and the voltage compensation module 22. The voltage detecting module 24 is configured to detect the piezoelectric voltage generated by the deformation of each mask plate 11, and feedback the parameter of the piezoelectric voltage to the voltage compensation module 22. The voltage compensation module 22 applies the reverse compensation voltage which has the same size and opposite direction with the piezoelectric voltage to each mask plate 11 based on the obtained parameter of the piezoelectric voltage. In this way, the compensation voltage is determined by directly detecting the piezoelectric voltage generated by the deformation of each mask plate 11. It is unnecessary to set the first sensor 13 and/or the second sensor 3 to obtain the deformation parameter of each mask plate 11, thereby simplifying the process flow and effectively reducing the manufacturing and use costs.

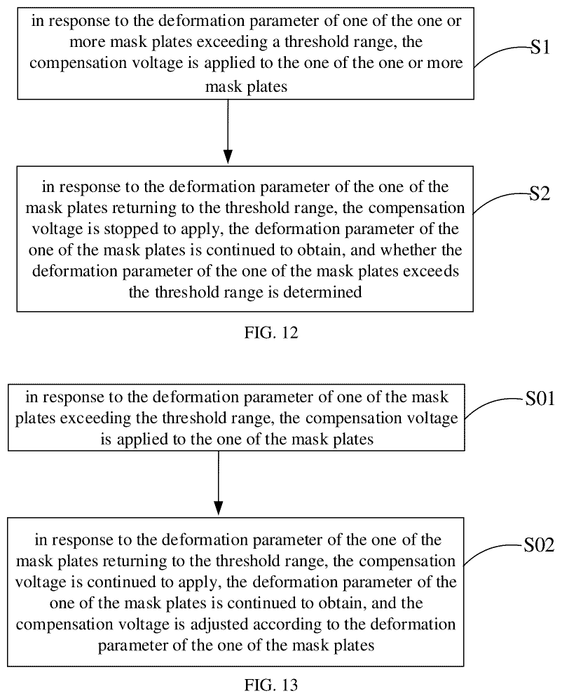

Referring to FIG. 12, FIG. 12 is a flowchart of a method of an evaporation device applying a compensation voltage according to one embodiment of the present disclosure. In some embodiments, the control circuit 2 applying the compensation voltage to the each mask plate 11 according to the deformation parameter of each mask plate 11, includes the following operations.

S1: in response to the deformation parameter of one of the one or more mask plates exceeding a threshold range, the compensation voltage is applied to the one of the one or more mask plates.

During the implementation process, a threshold range is pre-set. Within the threshold range, the deformation of the mask plate 11 will not affect the regular deposition of organic materials on the array substrate. In some embodiments, when the first sensor 13 and/or the second sensor 3 detect that the deformation direction and deformation size of each mask plate 11 are within the threshold range, the voltage compensation module 22 of the control circuit 2 will not work, and when the first sensor 13 and/or the second sensor 3 detect that the deformation direction and the deformation size of one of the mask plates 11 exceed the threshold range, the voltage compensation module 22 starts to apply the compensation voltage to the one of the mask plates 11. In this way, the control circuit 2 will apply the compensation voltage to one of the mask plates 11 after the deformation of the one of the mask plates 11 exceeds a certain degree, thereby reducing the energy consumption of the evaporation process and further reducing the process cost. The threshold range of deformation may be an absolute value, or may be a relative value, such as the ratio of a deformed size to an original size.

In other embodiments, the control circuit 2 may also determine whether to apply the compensation voltage to one of the mask plates 11 according to whether the temperature of the one of the mask plates 11 exceeds the threshold range. Alternatively, the control circuit 2 may determine whether to apply the compensation voltage to one of the mask plates 11 based on whether the piezoelectric voltage generated by the deformation of the one of the mask plates 11 exceeds a threshold. The threshold range of the temperature change may be an absolute value, or may be a relative value, such as the ratio of an increased temperature to an initial temperature (such as room temperature).

S2: in response to the deformation parameter of the one of the mask plates returning to the threshold range, the compensation voltage is stopped to apply, the deformation parameter of the one of the mask plates is continued to obtain, and whether the deformation parameter of the one of the mask plates exceeds the threshold range is determined.

During the specific implementation process, after the control circuit 2 applies the compensation voltage to one of the mask plates 11, the one of the mask plates 11 generates a compensation deformation to return the deformation parameter of the one of the mask plates 11 to the threshold range. After the deformation parameter of the one of the mask plates 11 return to the threshold range, the control circuit 2 stops applying the compensation voltage to the one of the mask plates 11, thereby further reducing the process energy consumption. It should be understood that the deformation of the mask plate 11 takes a certain amount of time, and it needs some time from the deformation parameter of the mask plate 11 returning to the threshold range to the deformation again. During this period, the control circuit 2 stops applying the compensation voltage to the mask plate 11, thereby reducing a process energy consumption.

In some embodiments, after the control circuit 2 stops applying the compensation voltage, the control circuit 2 may continue to acquire the deformation direction and deformation size of the one of the mask plates 11 through the first sensor 13 and/or the second sensor 3, or the control circuit 2 acquires the temperature of the one of the mask plates11, and judge whether it is beyond the threshold range, to determine whether to apply the compensation voltage to the one of the mask plates 11 again. In other embodiments, the control circuit 2 may also obtain the piezoelectric voltage generated by the deformation of one of the mask plates 11 through the voltage detecting module 24, and determine whether the piezoelectric voltage exceeds the threshold range, thereby determining whether to apply the compensation voltage to the one of the mask plates 11 again.

Referring to FIG. 13, FIG. 13 is a flowchart of a method of an evaporation device applying a compensation voltage according to another embodiment of the present disclosure. In some embodiments, the control circuit 2 applying the compensation voltage to one of the mask plates 11 according to the deformation parameter of the one of the mask plates 11, includes the following operations:
S01: in response to the deformation parameter of one of the mask plates exceeding the threshold range, the compensation voltage is applied to the one of the mask plates.
S02: in response to the deformation parameter of the one of the mask plates returning to the threshold range, the compensation voltage is continued to apply, the deformation parameter of the one of the mask plates is continued to obtain, and the compensation voltage is adjusted according to the deformation parameter of the one of the mask plates.

During the specific implementation process, after the control circuit 2 applies the compensation voltage to the one of the mask plates 11, the one of the mask plates 11 generates the compensation deformation to return the deformation parameter of the one of mask plates 11 to the threshold range. After the deformation parameter of the one of the mask plates 11 returns to the threshold range, the control circuit 2 continues to apply the compensation voltage to the one of the one or more mask plates 11 to keep the one of the mask plates 11 in the state before the deformation as far as possible. It should be understood that, if the deformation parameter of the one of the mask plates 11 return to the threshold range, and the factor that causes the deformation of the one of the mask plates 11 (such as high temperature) do not disappear, the control circuit 2 will continue to apply the compensation voltage to the one of the mask plates 11, thereby keeping the one of the mask plates 11 in the state before deformation.

During the continuous application of the compensation voltage by the control circuit 2, the control circuit 2 may continue to obtain the deformation direction and the deformation size of the one of the mask plates 11 through the first sensor 13 and/or the second sensor 3, or obtain the temperature of the one of the mask plates 11, and adjust the size of the compensation voltage based on the deformation direction and the deformation size of the one of the mask plates 11 or the temperature of the one of the mask plates 11. In other embodiments, the control circuit 2 may also continue to acquire the piezoelectric voltage generated by the deformation of the one of the mask plates 11 through the voltage detecting module 24, and adjust the size of the compensation voltage according to the piezoelectric voltage. This method may reduce the deformation of the mask plate 11 relative to the initial shape caused by the compensation voltage because of the disappearance of a factor (such as the high temperature) that causes the deformation of the mask plate 11.

The evaporation device provided by the some embodiments of the present disclosure includes the mask plate assembly 1 and the control circuit 2. The control circuit 2 is electrically connected to the mask plate 11 through the electrode pair 12. The control circuit 2 is configured to obtain the deformation parameter of each mask plate 11 and apply the compensation voltage to each mask plate 11 based on the deformation parameter of each mask plate 11. Each mask plate 11 may have the reverse piezoelectric effect and generate the reset deformation to compensate for the deformation caused by heat or its own gravity, thereby avoiding the occurrence of irregular organic material deposition caused by the deformation of each mask plate 11, and effectively improving the stability of the product.

For ordinary skilled person in the art, it is obvious that the present disclosure is not limited to the details of the above exemplary embodiments, and the present disclosure may be realized in other specific forms without departing from the spirit or basic features of the present disclosure. Therefore, from any point of view, the embodiments should be regarded as exemplary and non-restrictive. The scope of the present disclosure is defined by the appended claims rather than the above description, so it is intended to include all changes within the meaning and scope of the similar elements of the claims in the present disclosure. Any accompanying drawings in the claims should not be regarded as limiting the claims involved.

The above shows only embodiments of the present disclosure and does not limit the scope of the present disclosure. Any equivalent structure or equivalent process transformation performed based on the specification and accompanying drawings of the present disclosure, directly or indirectly applied in other related fields, shall be equivalently covered by the present disclosure.

What is claimed is:

1. A mask plate assembly, comprising:
one or more mask plates, wherein each of the one or more mask plates defines a plurality of openings; and
one or more electrode pairs, wherein each of the one or more electrode pairs comprises two electrodes, the two electrodes are disposed on one of the one or more mask plates and spaced apart from each other, and the two electrodes are configured to apply a compensation voltage to the one of the one or more mask plates;
wherein each of the one or more mask plates comprises a piezoelectric material.

2. The mask plate assembly according to claim 1, wherein
each of the one or more mask plates is made of the piezoelectric material, and the piezoelectric material is a piezoelectric ceramic or an alloy of the piezoelectric ceramic and a metal.

3. The mask plate assembly according to claim 1, wherein
the mask plate assembly comprises a plurality of electrode pairs; and the plurality of electrode pairs are disposed in different regions of one of the one or more mask plates at intervals;
wherein one of the two electrodes of the same one of the one or more electrode pairs is disposed on one of two opposite surfaces of the one of the one or more mask plates; and the other of the two electrodes of the same one of the one or more electrode pairs is disposed on the other of two opposite surfaces of the one of the one or more mask plates.

4. The mask plate assembly according to claim 3, wherein
the compensation voltages applied by different electrode pairs are the same; or
the compensation voltages applied by different electrode pairs are different.

5. The mask plate assembly according to claim 3, wherein
the plurality of electrode pairs are arranged in parallel and spaced apart from each other.

6. The mask plate assembly according to claim 1, further comprising one or more first sensors, wherein each of the one or more first sensors is arranged on a corresponding one of the one or more mask plates, and each of the one or more first sensors is configured to detect a deformation direction and a deformation size of the corresponding one of the one or more mask plates or detect a temperature of the corresponding one of the one or more mask plates.

7. The mask plate assembly according to claim 6, wherein each of the one or more first sensors is a displacement sensor or a temperature sensor.

8. The mask plate assembly according to claim 6, further comprising a main mask frame and a plurality of sub mask frames, wherein the plurality of sub mask frames are arranged on the main mask frame, the number of the one or more mask plates is two or more, each of the plurality of sub mask frames is arranged with one of the one or more mask plates, and only one of the one or more mask plates is arranged with the one or more first sensors.

9. An evaporation device, comprising:
a mask plate assembly, comprising:
one or more mask plates, wherein each of the one or more mask plates defines a plurality of openings; and
one or more electrode pairs, wherein each of the one or more electrode pairs comprises two electrodes, the two electrodes are disposed on one of the one or more mask plates and spaced apart from each other, and the two electrodes are configured to apply a compensation voltage to the one of the one or more mask plates; wherein each of the one or more mask plates comprises a piezoelectric material; and
a control circuit, electrically connected to each of the one or more mask plates, wherein the control circuit is configured to obtain a deformation parameter of each of the one or more mask plates, and apply a compensation voltage to each of the one or more mask plates according to the deformation parameter of each of the one or more mask plates, so that each of the one or more mask plates occurs a reverse piezoelectric effect.

10. The evaporation device according to claim 9, wherein
the deformation parameter of each of the one or more mask plates comprises a piezoelectric voltage generated by a deformation of each of the one or more mask plates;
the control circuit comprises a voltage detecting module and a voltage compensation module, the voltage detecting module is configured to detect the piezoelectric voltage generated by the deformation of each of the one or more mask plates, and the voltage compensation module is configured to apply the compensation voltage to each of the one or more mask plates; and
the compensation voltage and the piezoelectric voltage are equal in size and opposite in direction.

11. The evaporation device according to claim 9, further comprising a second sensor;
wherein the second sensor is arranged outside each of the one or more mask plates, and configured to detect a deformation direction and a deformation size of each of the one or more mask plates or detect a temperature of each of the one or more mask plates.

12. The evaporation device according to claim 9, wherein
the deformation parameter of each of the one or more mask plates comprises a deformation direction and a deformation size of the each of the one or more mask plates, the control circuit comprises a calculation module and a voltage compensation module, the calculation module is configured to calculate a piezoelectric voltage generated by a deformation of each of the one or more mask plates according to the deformation direction and the deformation size of the each of the one or more mask plates, the voltage compensation module is configured to apply the compensation voltage to each of the one or more mask plates, and the compensation voltage and the piezoelectric voltage are equal in size and opposite in direction; or
the deformation parameter of each of the one or more mask plates comprises a temperature of each of the one or more mask plates, the control circuit comprises a storage module and the voltage compensation module, the storage module is configured to store a corresponding relationship between the temperature and the compensation voltage of each of the one or more mask plates, the voltage compensation module is configured to obtain the compensation voltage according to the temperature of each of the one or more mask plates and the corresponding relationship between the temperature and the compensation voltage of each of the one or more mask plates, and apply the compensation voltage to each of the one or more mask plates.

13. The evaporation device according to claim 9, wherein
the control circuit applying the compensation voltage to each of the one or more mask plates according to the deformation parameter of each of the one or more mask plates, comprises:
in response to the deformation parameter of one of the one or more mask plates exceeding a threshold range, applying the compensation voltage to the one of the one or more mask plates; and
after the control circuit applying the compensation voltage to each of the one or more mask plates according to the deformation parameter of each of the one or more mask plates, the evaporation device also comprises:
in response to the deformation parameter of one of the one or more mask plates returning to the threshold range, stopping applying the compensation voltage, continuing to obtain the deformation parameter of the one of the one or more mask plates, and determining whether the deformation parameter of the one of the one or more mask plates exceeds the threshold range; or
in response to the deformation parameter of one of the one or more mask plates returning to the threshold range, continuously applying the compensation voltage, continuously obtaining the deformation parameter of the one of the one or more mask plates, and adjusting the size of the compensation voltage according to the deformation parameter of the one of the one or more mask plates.

14. The evaporation device according to claim 9, wherein
each of the one or more mask plates is made of the piezoelectric material, and the piezoelectric material is a piezoelectric ceramic or an alloy of the piezoelectric ceramic and a metal.

15. The evaporation device according to claim 9, wherein
the mask plate assembly comprises a plurality of electrode pairs; and the plurality of electrode pairs are disposed in different regions of one of the one or more mask plates at intervals;
wherein one of the two electrodes of the same one of the one or more electrode pairs is disposed on one of two opposite surfaces of the one of the one or more mask plates; and the other of the two electrodes of the same one of the one or more electrode pairs is disposed on the other of two opposite surfaces of the one of the one or more mask plates.

16. The evaporation device according to claim 15, wherein
the compensation voltages applied by different electrode pairs are the same; or
the compensation voltages applied by different electrode pairs are different.

17. The evaporation device according to claim 15, wherein
the plurality of electrode pairs are arranged in parallel and spaced apart from each other.

18. The evaporation device according to claim 9, further comprising one or more first sensors, wherein each of the one or more first sensors is arranged on a corresponding one of the one or more mask plates, and each of the one or more first sensors is configured to detect a deformation direction and a deformation size of the corresponding one of the one or more mask plates or detect a temperature of the corresponding one of the one or more mask plates.

19. The evaporation device according to claim 18, wherein each of the one or more first sensors is a displacement sensor or a temperature sensor.

20. The evaporation device according to claim 18, further comprising a main mask frame and a plurality of sub mask frames, wherein the plurality of sub mask frames are arranged on the main mask frame, the number of the one or more mask plates is two or more, each of the plurality of sub mask frames is arranged with one of the one or more mask plates, and only one of the one or more mask plates is arranged with the one or more first sensors.
